(19) United States
(12) Patent Application Publication
(10) Pub. No.: US 2008/0157275 A1
(43) Pub. Date: Jul. 3, 2008

(54) DISPLAY DEVICE AND METHOD OF MANUFACTURING THE SAME

(75) Inventor: Takuji Imamura, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Mitsubishi Electric Corporation, Chiyoda-ku (JP)

(21) Appl. No.: 11/852,732

(22) Filed: Sep. 10, 2007

(30) Foreign Application Priority Data
Nov. 9, 2006 (JP) 2006-303826

(51) Int. Cl. H01L 27/12; H01L 21/782

(52) U.S. Cl. 257/532; 438/393; 257/E27.112; 257/E21.535

(57) ABSTRACT

A display device includes a substrate, a capacitor lower electrode having a polycrystalline silicon film formed over the substrate and a contact metal film provided over the polycrystalline silicon film, a gate insulating film formed over the capacitor lower electrode and a gate metal electrode formed to a position opposing the capacitor lower electrode over the gate insulating film and formed to be disposed inner side of the capacitor lower electrode in top view.

### BACKGROUND OF THE INVENTION

1. Field of the Invention

The present invention relates to a display device and a method of manufacturing the same.

2. Description of Related Art

Along with the full-scale development of advanced information society and rapid expansion of multimedia systems in recent years, an importance of LCD (Liquid Crystal Display) and organic EL (Electro Luminescence) display device is increasing more than ever. As a driving system of pixels for these display devices, an active matrix system using TFTs (Thin Film Transistor) arranged in array is widely employed.

Specially the liquid crystal display is one of common thin panels which consumes less power and is easily miniaturized and lightened. Therefore the liquid crystal displays are widely used for personal computer monitors and handheld terminal device monitors. Moreover in recent years, the liquid crystal displays are replacing conventional cathode ray tube display devices for use as television.

In general, a TFT is manufactured by forming an island shaped silicon film over an insulating substrate such as glass and forming a gate insulating film and a gate electrode over the island shaped silicon film. At the same time as forming the circuit for the TFT, a capacitor electrode is formed. Japanese Unexamined Patent Application Publication No. 2002-311453 discloses that a capacitor is formed by a lower part auxiliary capacitance layer and upper part metal electrode with an insulating film interposed therebetween.

As for a TFT, a MOS structure using a semiconductor film is often used. For the MOS structure, there are some variety such as inversely staggered and top-gate types. For the semiconductor film, there are an amorphous silicon thin film, a polycrystalline silicon thin film, and so on. They are appropriately selected according to the usage and performance of the liquid crystal display. For TFTs of a small panel, the polycrystalline silicon thin film is often used. TFTs using the polycrystalline silicon thin film have high mobility. Accordingly, when using such TFT as a pixel switching device, the TFT can be miniaturized and the panel can be made to be high-resolution. Furthermore, TFTs using polycrystalline silicon thin film can be used for peripheral circuit part for driving the pixel switching devices.

On the other hand, to reduce the manufacturing cost of TFT array substrates, reduction in number of mask processes has been considered. Therefore, in order to electrically connect a semiconductor thin film, a gate electrode or a signal line with an upper layer pixel electrode, a manufacturing method for forming contact holes in insulating films formed therebetween in one process is used. Then the top layer pixel electrode is connected to the semiconductor thin film and the conductive films respectively via the contact hole.

As described above, the semiconductor thin film is electrically connected with the pixel electrode formed from a transparent conductive film such as ITO. However, when directly contacting the semiconductor thin film with the ITO, a non-Ohmic and high resistance contact is indicated. Therefore, a structure having a contact metal film such as Mo, Cr, W and Ti which is provided over the semiconductor thin film is under consideration. With this structure, a potential supplied from ITO is once received by the contact metal film and then supplied from the contact metal film to the semiconductor thin film.

A conventional display device is described hereinafter in detail with reference to FIGS. 6 and 7. FIG. 6 is a plan view of a capacitor which is a part of the conventional display device. FIG. 7 is a cross-sectional diagram of the capacitor which is a part of the conventional display device taken along the line VII-VII of FIG. 6. As shown in FIGS. 6 and 7, in the conventional display device, over a substrate 1 such as an insulating substrate, a silicon nitride film 2 and silicon oxide film 3 are formed as foundation films. A semiconductor thin film 14 is formed to a predetermined position over the silicon oxide film 3. Furthermore, a contact metal film 5 is formed over the semiconductor thin film 14. Over the contact metal film 5/semiconductor thin film 14, a gate insulating film 6 is formed to cover them. Then to the position opposing the contact metal film 5 over the gate insulating film 6, a gate metal electrode 7 is formed. One side of a capacitor electrode, a capacitor lower electrode, is formed by the semiconductor thin film 14 and contact metal film 5 formed over the semiconductor thin film 14. The gate metal electrode 7 is disposed to oppose the capacitor lower electrode. Furthermore, the gate insulating film 6 is formed between the gate metal electrode 7 and the capacitor lower electrode.

In this case, the gate metal electrode 7 is formed to completely cover the capacitor lower electrode formed of the contact metal film 5/semiconductor thin film 14. More specifically, in the conventional display device, the contact metal film 5/semiconductor thin film 14 which is one side of the capacitor electrode is disposed on the inner side of the gate metal electrode 7 which is the other capacitor electrode in top view, and is covered with. Therefore, step coverage of the gate insulating film 6 in the end part of the contact metal film 5/semiconductor thin film 14 is deteriorated and a gate dielectric strength is reduced. Thus conventional display device is inferior in reliability and yield.

As described above, in the conventional display device, there were problems that step coverage of the gate insulating film in the end part of the contact metal film/semiconductor thin film is poor and thus gate dielectric strength is low.

The present invention seeks to solve one or more of the above problems, or to improve upon those problems at least in part and aims to provide a display device with high yield and reliability and a method of manufacturing the same.

### SUMMARY OF THE INVENTION

According to an embodiment of the present invention, there is provided a display device that includes a substrate, a capacitor lower electrode having a polycrystalline silicon film formed over the substrate and a contact metal film provided over the polycrystalline silicon film, a gate insulating film formed over the capacitor lower electrode and a gate metal electrode formed to a position opposing the capacitor lower electrode over the gate insulating film and formed to be disposed inner side of the capacitor lower electrode in top view.

The present invention is able to provide a display device with high yield and reliability and a method of manufacturing the same.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a plan view showing the configuration of a TFT array substrate used in a display device according to an embodiment of the present invention;

FIG. 2 is a plan view of a capacitor which is a part of the display device according to a first embodiment of the present invention;

FIG. 3 is a cross-sectional diagram of the capacitor which is a part of the display device according to the first embodiment of the present invention;

FIG. 4 is a plan view of a capacitor which is a part of the display device according to a second embodiment of the present invention;

FIG. 5 is a cross-sectional diagram of the capacitor which is a part of the display device according to the second embodiment of the present invention;

FIG. 6 is a plan view of a capacitor which is a part of a conventional display device; and

FIG. 7 is a cross-sectional diagram of the capacitor which is a part of the conventional display device.

### DESCRIPTION OF THE PREFERRED EMBODIMENTS

The invention will be now described herein with reference to illustrative embodiments. The explanation below is regarding the embodiments and the present invention is not limited to the embodiments illustrated for explanatory purposes.

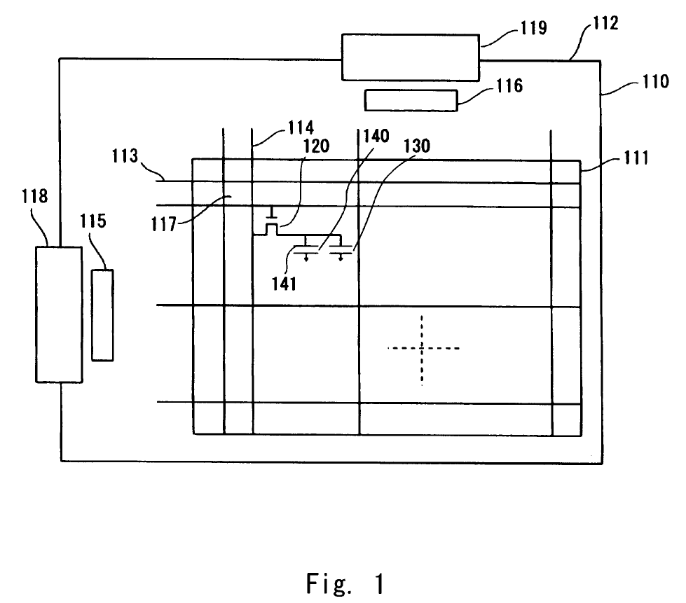

FIG. 1 is a plan view showing the configuration of a TFT array substrate used in a display device according to an embodiment of the present invention. An embodiment of the present invention is described hereinafter in detail with reference to FIG. 1. As a display device having this TFT array substrate, there are flat panel displays including a liquid crystal display and organic EL display etc. In this embodiment, the liquid crystal display which is an example of the display device is described.

The display device according to the embodiment of the present invention includes a substrate 110. The substrate 110 is for example a TFT array substrate having TFTs 120 arranged in array. To the substrate 110, a display area 111 and a frame area 112 surrounding the display area 111 are provided. A plurality of gate lines (scanning signal lines) 113 and a plurality of signal lines (display signal lines) 114 are formed in the display area 111. The plurality of gate lines 113 are provided in parallel. Likewise, the plurality of signal lines 114 are provided in parallel. The gate lines 113 and the signal lines 114 are formed to cross each other. The gate lines 113 and the signal lines 114 are orthogonal. Moreover, an area surrounded by the adjacent gate lines 113 and the signal lines 114 is a pixel 117. Accordingly in the substrate 110, pixels 117 are arranged in matrix.

Additionally in the frame area 112 of the substrate 110, a scanning signal driving circuit unit 115 and a display signal driving circuit unit 116 are provided. The gate lines 113 are extended from the display area 111 to the frame area 112. Furthermore, the gate lines 113 are connected with the scanning signal driving circuit unit 115 at the end part of the substrate 110. The signal lines 114 are also extended from the display area 111 to the frame area 112. The signal lines 114 are connected with the display signal driving circuit unit 116 at the end part of the substrate 110. An external line 118 is connected near the scanning signal driving circuit unit 115. Furthermore, an external line 119 is connected near the display signal driving circuit unit 116. The external lines 118 and 119 are wiring boards such as FPC (Flexible Printed Circuit).

Various signals are externally supplied to the scanning signal driving circuit unit 115 and the display signal driving circuit unit 116 via the external lines 118 and 119. The scanning signal driving circuit unit 115 supplies a gate signal (scanning signal) to the gate line (scanning signal line) 113 according to an external control signal. By the gate signal, the gate lines 113 are selected sequentially. The display signal driving circuit unit 116 supplies a display signal to the signal lines 114 according to an external control signal or display data. This enables to supply a display voltage according to the display data to each of the pixels 117.

In the pixel 117, at least one TFT 120, capacitor 130 and liquid crystal pixel 140 are formed. The capacitor 130 includes a capacitor upper electrode and a capacitor lower electrode. The capacitor upper electrode and the capacitor lower electrode are disposed to oppose each other with an insulating film interposed therebetween. Furthermore, the liquid crystal pixel 140 includes a pixel electrode 141 and an opposing electrode. The pixel electrode 141 and the opposing electrode are disposed to oppose each other with liquid crystal held therebetween. Note that the opposing electrode is formed to an opposing substrate described later and is connected with the liquid crystal layer in common. The TFT 120 is disposed near the intersection of the signal line 114 and gate line 113. For example, this TFT 120 supplies the display voltage to the pixel electrode. That is, by the gate signal from the gate line 113, the TFT 120, which is a switching device, is turned on. This enables to apply the display voltage to the pixel electrode connected to a signal line of the TFT from the signal line 114. Moreover, an electric field according to the display voltage is generated between the pixel electrode and the opposing electrode. Moreover, even when the display voltage is not applied to the pixel electrode 141, the charge in the pixel electrode 141 can be retained by the capacitor 130. Note that an alignment layer (not shown) is formed over the surface of the substrate 110.

Furthermore, the opposing substrate is disposed opposite to the TFT array substrate. The opposing substrate is for example a color filter substrate and disposed to the visible side. To the opposing substrate, a color filter, a black matrix (BM), an alignment layer, and so on are formed. In addition, the liquid crystal layer is held between the substrate 110 and the opposing substrate. More specifically, liquid crystal is filled between the substrate 110 and the opposing substrate. Furthermore, a polarizing plate and retardation film or the like are provided to the outside surface of the substrate 110 and the opposing substrate. Moreover, a backlight unit or the like is provided to the non-visible side of a liquid crystal display panel.

The liquid crystal is driven by the electric field between the pixel electrode and the opposing electrode and an alignment direction of the liquid crystal between the substrates changes. This changes the polarization state of the light passing through the liquid crystal layer. That is, the light that has passed the polarizing plate and became a linearly polarized light changes its polarization state by the retardation film and the liquid crystal layer. More specifically, in a transparent area, the light from the backlight unit becomes a linearly polarized light by the polarizing plate provided to the TFT array substrate side. Furthermore, by passing through the retardation film of the TFT array substrate side, the liquid crystal layer, and the retardation film of the opposing substrate side, the linearly polarized light changes its polarization state. On the other hand, in a reflection area, an outside light entered from the visible side of the liquid crystal display panel becomes a linearly polarized light by the polarizing plate of the opposing substrate. Then, by passing through the retardation film of the opposing substrate and the liquid crystal layer back and forth, this light changes its polarization state.

Thus, the amount of light passing through the polarizing plate of the opposing substrate side varies according to the polarization state. More specifically, among transmitted light transmitting from the backlight unit through the liquid crystal panel and reflected light reflected at the liquid crystal panel, the amount of light passing through the polarizing plate of the visible side varies. The alignment direction of the liquid crystal varies according to the applied display voltage. Therefore, by controlling the display voltage, the amount of light passing through the polarizing plate of the visible side can be changed. That is, by varying the display voltage to each pixel, a desired image can be displayed.

To be more specific, to display black, light is made to be linearly polarized light having almost same vibration direction (plane of polarization) as an absorption axis of the polarizing plate of the visible side by the retardation film and the liquid crystal layer. By this, almost all the light is blocked by the polarizing plate of the visible side and black can be displayed. On the other hand, to display white, light is made to be linearly polarized light in a direction almost orthogonal to the absorption axis of the polarizing plate of the visible side or circularly polarized light or the like by the retardation film and the liquid crystal layer. By this, as the light passes through the polarizing plate of the visible side, white can be displayed. As described above, the display voltage applied to each pixel can be controlled by the gate signal and the source signal. This changes the alignment of the liquid crystal layer and the polarization state varies according to the display voltage. Thus a desired image can be displayed.

### First Embodiment

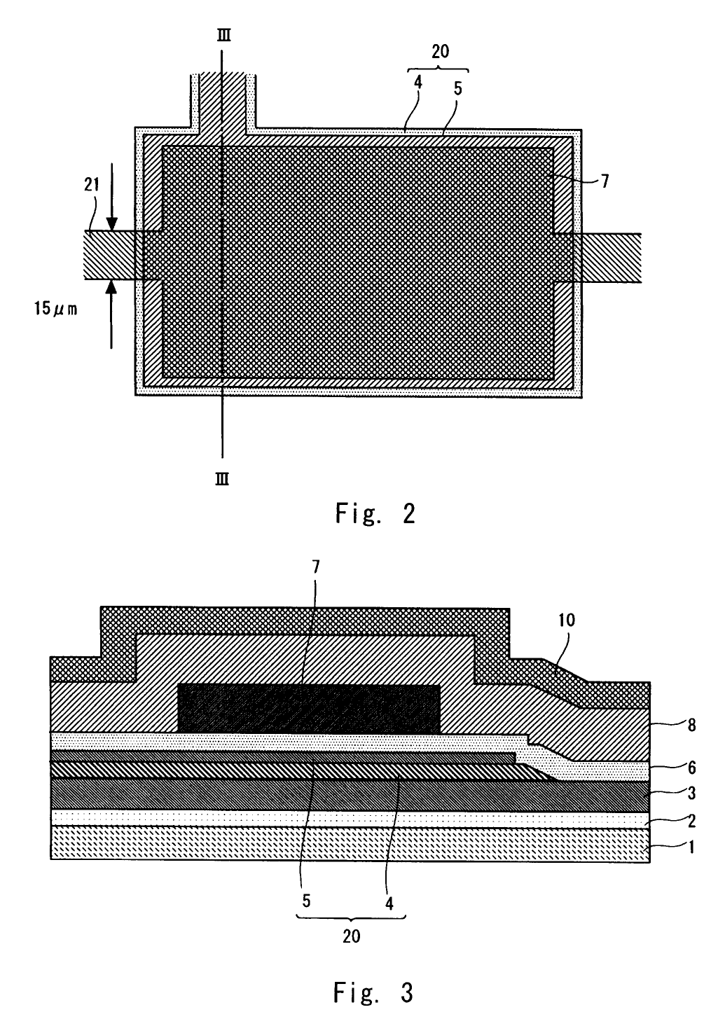

A display device of a first embodiment is described hereinafter in detail with reference to FIGS. 2 and 3. FIG. 2 is a plan view of a capacitor 130 which is a part of the display device according to the first embodiment. FIG. 3 is a cross-sectional diagram of the capacitor 130 which is a part of the display device according to the first embodiment taken along the line III-III of FIG. 2. Firstly, the configuration of the display device according to the first embodiment is described. A silicon nitride film 2 and a silicon oxide film 3 are formed over a substrate 1 such as an insulating substrate having transparency including a glass substrate and a quartz substrate. Note that as the configuration of the TFT is identical to a top-gate type polycrystalline silicon TFT that has been widely used, the explanation is omitted here.

A polycrystalline silicon film 4 is formed to a predetermined position over the silicon oxide film 3. Furthermore, a contact metal film 5 is formed over the polycrystalline silicon film 4. The contact metal film 5 is formed in a smaller area than the polycrystalline silicon film 4 and disposed not to protrude from the polycrystalline silicon film 4. Here, the laminated structure of the polycrystalline silicon film 4 and the contact metal film 5 is to be a capacitor lower electrode 20. A gate insulating film 6 is formed over the contact metal film 5 to cover the capacitor lower electrode 20.

Then to the position opposing the capacitor lower electrode 20 over the gate insulating film 6, a gate metal electrode 7 is formed. The gate metal electrode 7 is to be the capacitor upper electrode. At this time, the gate metal electrode 7 is formed inner side than the capacitor lower electrode 20 and preferably inner side than the contact metal film 5. That is, the capacitor lower electrode 20 which is one side of the capacitor electrode is disposed to protrude outside from the gate metal electrode 7 in top view. Note that over the entire periphery of the capacitor lower electrode 20, the gate metal electrode 7 is not disposed to the edge part of the capacitor lower electrode 20. With such structure, step coverage of the gate insulating film 6 in the end part of the capacitor lower electrode 20 can be favorable. However, only a routing line 21 is patterned to override the edge part of the capacitor lower electrode 20. The routing line 21 and the gate metal electrode 7 is formed in the same layer in an integrated manner. Thus the conductive layer of the same layer as the gate metal electrode 7 except the routing line 21 is not disposed over the edge part of the capacitor lower electrode 20 for the entire periphery of the capacitor lower electrode 20. Moreover, the width of the routing line 21 is not more than 15 μm. The portion for the routing line 21 to override the edge part of the capacitor lower electrode 20 can be made small by this. This prevents dielectric breakdown from generating between the routing line 21 and capacitor lower electrode 20. Thus a display device with high yield and reliability can be achieved.

Moreover, an interlayer insulating film 8 is formed to cover the gate metal electrode 7 over the gate metal electrode 7. A protective film 10 is formed over the interlayer dielectric 8. In this embodiment, two routing lines 21 are taken from the gate metal electrode 7. The two routing lines 21 are taken from the end parts of the gate metal electrode 7 which are opposing each other. The routing line 21 connects the gate metal electrodes 7 of adjacent pixels, for example. A common voltage is supplied to the gate metal electrode 7 via the routing line 21. On the other hand, the capacitor lower electrode 20 is connected with a drain of the TFT 120, for example and supplied with a display voltage. Then a potential is retained by the capacitor 130 formed of the gate metal electrode 7.

A manufacturing method according to the first embodiment is described hereinafter. Firstly, a foundation film is formed over the insulating substrate 1 with transparency such as a glass substrate or a quartz substrate. As for the foundation film, a silicon nitride film 2, a silicon oxide film 3 or a stacked film thereof can be used. Next, an amorphous silicon film having thickness from 50 to 70 nm is formed by plasma CVD method. After that, the amorphous silicon is melted by excimer layer annealing or YAG laser annealing or the like, cooled and solidified to obtain a polycrystalline silicon film. Then a resist pattern is formed by photolithography over the polycrystalline silicon film. The polycrystalline silicon film is patterned using the resist pattern by dry etching to process the polycrystalline silicon film 4 to be an island shape. After that, the resist pattern is removed. In this way, the polycrystalline silicon film 4 is formed to the place to be the TFT 120 and the place to be the capacitor 130.

After processing the polycrystalline silicon film 4 to be island shape, the contact metal film 5 such as Mo, Cr, W and Ti is formed thereover. After that, the contact metal film 5 is patterned to remain in the place to be a S/D region (source/drain region) of the TFT 120 and the place to be the capacitor 130. Then the capacitor lower electrode 20 is formed.

After forming the polycrystalline silicon film 4 and the contact metal film 5, the gate insulating film 6 is formed over the entire surface of the substrate 1 by plasma CVD method to cover the polycrystalline silicon film 4 and the contact metal film 5. As the result, the gate insulating film 6 covers the polycrystalline silicon film 4/contact metal film 5 in the place to be the TFT 120 and the capacitor lower electrode 20 in the place to be the capacitor 130. As for the gate insulating film 6, a silicon nitride film (SiNx) a silicon oxide film (SiOx), a silicon oxynitride film (SiOxNy) or a stacked film thereof can be used. After forming the gate insulating film 6, a conductive film to be the gate metal electrode 7 is formed by sputtering method using DC magnetron. The conductive film is Mo, Cr, W, Al, Ta or an alloy film mainly including these components.

After forming the conductive film to be the gate metal electrode 7, a patterning is performed. Then a gate electrode of the place to be the TFT 120 and the gate metal electrode 7 of the place to be the capacitor upper electrode for the capacitor 130 are formed at the same time. At this time, the capacitor upper electrode is formed inner side than the capacitor lower electrode 20 and especially inner side than the contact metal film 5. That is, the capacitor lower electrode 20 which is one side of the capacitor electrode is formed outside than the gate metal electrode 7 which is the other capacitor electrode in top view. However, the routing line 21 of the gate metal electrode 7 is patterned to override the edge part of the capacitor lower electrode 20. At this time, the width of the routing line 21 is made to be not more than 15 μm.

Here the routing line 21 overrides the edge part of the capacitor lower electrode 20. Therefore, if the coverage of the gate insulating film 6 over the capacitor lower electrode 20 is poor, dielectric breakdown may be generated between the routing line 21 and the capacitor lower electrode 20. In this embodiment, as the width of the routing line 21 is made to be not more than 15 μm, the portion for the routing line 21 to override the edge part of the capacitor lower electrode 20 can be made small. This prevents dielectric breakdown from generating between the routing line 21 and the capacitor lower electrode 20. Therefore, a display device with high yield and reliability can be achieved.

After forming the gate metal electrode 7, an impurity is introduced in order to form the S/D region of the TFT 120. The introduction of the impurity is performed by ion implantation or ion doping method. As an impurity element to be introduced, P or B can be used. When introducing P, an n type TFT can be formed. When introducing B, a p type TFT can be formed. Furthermore, the gate electrode of the same layer as the gate metal electrode 7 can be formed in two processes to be a gate electrode for an n type TFT and a gate electrode for a p type TFT. This enables to form n and p type TFTs over the same substrate. Incidentally, it may be LDD (Lightly Doped Drain) structure in order to improve reliability of the TFT. In this way, the TFT is formed in the S/D region.

After forming the S/D region of the TFT, the interlayer insulating film 8 formed of a silicon oxide film, a silicon nitride film, or the like is formed by plasma CVD method. The interlayer insulating film 8 is formed to cover the gate metal electrode 7 as for the capacitor 130. As for the TFT 120, it is formed to cover the gate electrode. After that, in order to activate the impurity introduced in the previous process, heat treatment of 400 degrees Celsius or more is applied.

After applying the heat treatment, a source drain metal to be the signal line 114 is formed over the interlayer insulating film 8 by sputtering method using DC magnetron. As for the signal line 114, for example Mo, Cr, W, Al, Ta or an alloy film mainly including these components can be used. Furthermore, the source drain metal must be electrically connected with its upper layer, the pixel electrode 114 formed of ITO or the like. Therefore, the source drain metal is a single layer of Mo, Cr, W, Ta or an alloy film mainly including these components, or a stacked layer structure where Mo, Cr, W, Ta or an alloy film mainly including these components is disposed to the top layer. By using these materials, it is possible to reduce contact resistance with the upper layer ITO. After forming the source drain metal, it is patterned by wet or dry etching to form the signal line 114.

After forming the signal line 114, the protective film 10 is formed over the interlayer insulating film 8 to cover the signal line 114 by plasma CVD method. A silicon nitride film formed by reacting SiH₄ and NH₃ can be used for the protective film 10. After forming the protective film 10, a contact hole for connecting the capacitor lower electrode 20, the gate metal electrode 7 or the signal line 114 with the upper layer pixel electrode 141 is formed by dry etching.

By etching the protective film 10, a contact hole reaching the signal line 114 can be formed. Furthermore, by etching the protective film 10 and the interlayer insulating film 8, a contact hole reaching the gate electrode (gate metal electrode 7) can be formed. Moreover, by etching the protective film 10, the interlayer insulating film 8 and the gate insulating film 6, a contact hole reaching the contact metal film 5 can be formed. By forming the contact hole reaching the signal line 114, the contact hole reaching the gate electrode (gate metal electrode 7) and the contact hole reaching the contact metal film 5 in one etching process, the manufacturing process can be simplified. This leads to improve the productivity.

After forming the contact holes, the pixel electrode 141 is formed over the protective film 10 by sputtering method using DC magnetron. Note that as for the pixel electrode 141, ITO or IZO primarily including indium oxide for example is used. Furthermore, the pixel electrode 141 is patterned to cover the contact holes. This enables to connect a drain of the TFT 120 with the pixel electrode 141 for example. Moreover, by a conductive pattern of the same layer as the pixel electrode 131, the signal line 119 and a source of the TFT 120 are connected. Therefore, a display voltage from the signal line 114 can be supplied to the pixel electrode 141 via the TFT 120. Additionally, the gate metal electrode 7 and the pixel electrode 141 are electrically connected. Thus a display voltage can be supplied to the gate metal electrode 7. The TFT array substrate is completed in this way. Then the TFT array substrate is used for an apparatus such as a liquid crystal display.

As described above, the gate metal electrode 7 is formed inner side of the capacitor electrode 20 in top view. Thus the step coverage of the gate insulating film 6 in the end part of the capacitor lower electrode 20 becomes favorable and a gate dielectric strength improves. Accordingly, a display device with high yield and reliability can be achieved.

### Second Embodiment

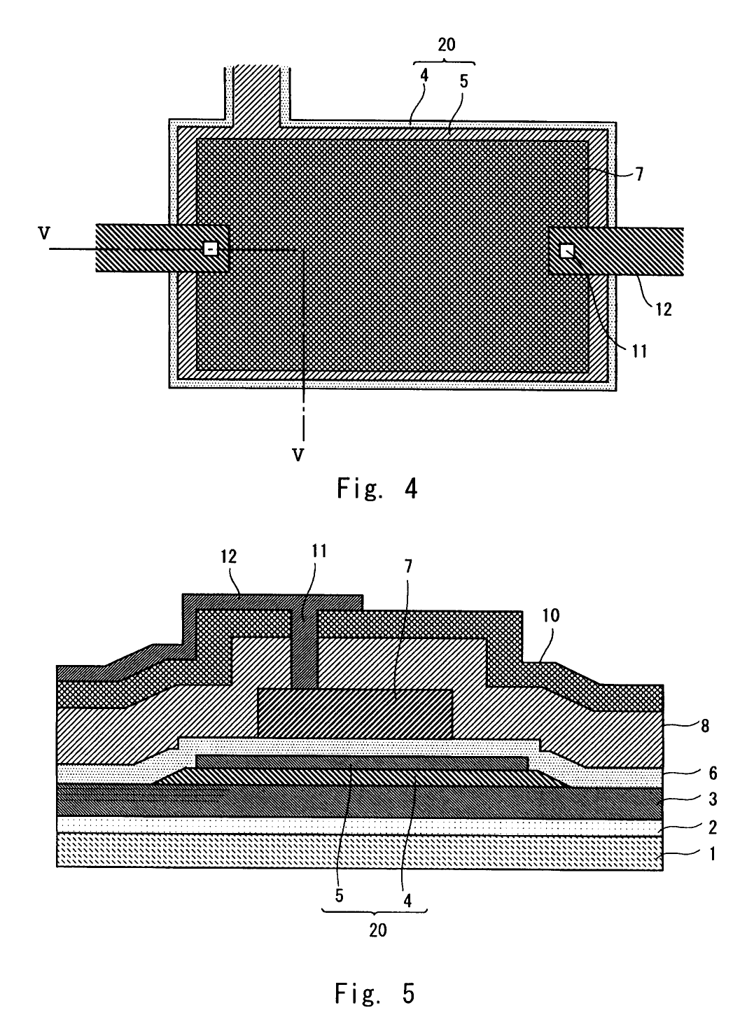

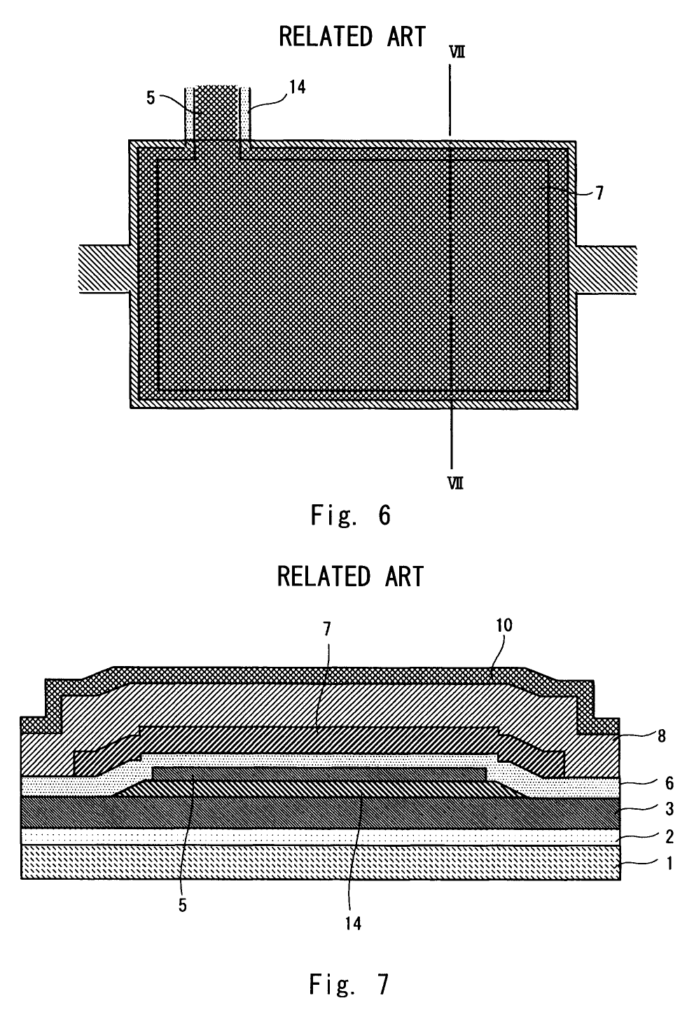

A second embodiment of the present invention is described hereinafter in detail with reference to FIGS. 4 and 5. FIG. 4 is a plan view of a capacitor 130 which is a part of the display device according to the second embodiment. FIG. 5 is a cross-sectional diagram of the capacitor 130 which is a part of the display device according to the second embodiment taken along the line V-V of FIG. 4.

The structure of the display device according to the second embodiment is described hereinafter. In the display device of the second embodiment, unlike the first embodiment, the routing line 21 is not formed to the gate metal electrode 7. More specifically, for the capacitor 130, all the metal of the same layer as the gate metal electrode 7 is formed inner side than the capacitor lower electrode 20. Note that over the entire periphery of the capacitor lower electrode 20, the gate metal electrode 7 is not disposed to the edge part of the capacitor lower electrode 20. In addition to the configuration of the first embodiment, a connection pattern 12 is formed over the protective film 10. The connection pattern 12 is formed from the same layer as the pixel electrode 141. A contact hole 11 reaching to the gate metal electrode 7 is formed from the connection pattern 12. Thus the connection pattern 12 is connected with the gate metal electrode 7 via the contact hole 11. Instead of the routing line 21 of the gate metal electrode 7 indicated in the first embodiment, the connection pattern 12 indicated in the second embodiment is used. By the connection pattern 12, the gate metal electrodes 7 of adjacent pixels are connected.

Here the connection pattern 12 is formed from the same conductive layer as the pixel electrode 141. Therefore, between the connection pattern 12 and the capacitor lower electrode 20, three layers of insulating film formed of the gate insulating film 6, the interlayer insulating film 8 and the protective film 10 are disposed. Furthermore, the connection pattern 12 is disposed over the protective film 10. That is, over the edge part of the capacitor lower electrode 20, the gate insulating film 6, the interlayer insulating film 8 and the protective film 10 are disposed in order from bottom. Then the connection pattern 12 is disposed over the protective film 10. By such configuration, the film thickness of the insulating film between the connection pattern 12 and the capacitor lower electrode 20 can be made thicker. Accordingly, it is possible to definitely prevent dielectric breakdown from generating in the edge part of the capacitor lower electrode 20. Therefore, a display device with high yield and reliability can be achieved.

A manufacturing method of the display device according to the second embodiment is described hereinafter in detail. From the formation of the silicon nitride film 2 over the substrate 1 to the formation of the conductive film to be the gate metal electrode 7, the processes are identical to the first embodiment so the explanation is omitted here. After forming the conductive film to be the gate metal electrode 7, the gate metal electrode 7 is patterned. Unlike the first embodiment, the routing line 21 is not formed for the pattern of the gate metal electrode 7. Therefore, all the metal of the same layer as the gate metal electrode 7 is patterned to be disposed inner side than the capacitor lower electrode 20.

After forming the gate metal electrode 7, as with the first embodiment, an impurity is introduced to form the S/D region of the TFT 120. From the formation of the S/D region of the TFT to the formation of the protective film 10, the processes are identical to the first embodiment so the explanation is omitted here. After forming the protective film 10, as with the first embodiment, a contact hole for connecting the capacitor lower electrode 20, the gate metal electrode 7 or the signal line 114 with the upper layer pixel electrode 141 is formed. At the same time, the contact hole 11 is formed to the protective film 10 and the interlayer insulating film 8. In this way, the contact hole 11 is formed to reach the gate metal electrode 7 across the protective film 10 and the interlayer insulating film 8.

After forming the contact hole 11, the pixel electrode 141 and the connection pattern 12 are formed over the protective film 10. Then the upper layer connection pattern 12 is connected with the gate metal electrode 7. Thus a common voltage can be supplied via the connection pattern 12. From the above processes, the TFT array substrate is completed.

As stated above, the step coverage of the gate insulating film 6 in the edge part of the capacitor lower electrode 20 is favorable and a gate dielectric strength improves. Moreover, each of the contact holes can be formed in the same process. Additionally, the pixel electrode 141 and the connection pattern 12 can be formed in the same process. Thus it is possible to prevent the number of processes from increasing. Accordingly the productivity can be improved. Therefore, the present invention enables to provide a display device with high productivity, reliability and yield.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A display device comprising:
a substrate;
a capacitor lower electrode having a polycrystalline silicon film formed over the substrate and a contact metal film provided over the polycrystalline silicon film;
a gate insulating film formed over the capacitor lower electrode; and
a gate metal electrode formed to a position opposing the capacitor lower electrode over the gate insulating film and formed to be disposed inner side of the capacitor lower electrode in top view.

2. The display device according to claim 1, further comprising a routing line taken from the gate metal electrode, having a width not more than 15 μm, and overriding an edge part of the capacitor lower electrode.

3. The display device according to claim 1, further comprising an upper layer connection pattern connected with the gate metal electrode via a contact hole, and overriding an edge part of the capacitor lower electrode.

4. A method of manufacturing a display device comprising:
forming a capacitor lower electrode including a polycrystalline silicon layer over a substrate and a contact metal film disposed over the polycrystalline silicon film;
forming a gate insulating film over the capacitor lower electrode; and
forming a gate metal electrode disposed inner side of the capacitor lower electrode over the gate insulating film in top view.

5. The method according to claim 4, wherein in the formation of the gate metal electrode, a routing line having a width not more than 15 μm and taken from the gate metal electrode is formed to override an edge part of the capacitor lower electrode.

6. The method according to claim 4, further comprising forming a connection pattern connected with the gate metal electrode via a contact hole to an upper layer of the gate metal electrode so as to override an edge part of the capacitor lower electrode.
